(19) United States
(12) Patent Application Publication
(10) Pub. No.: US 2002/0079555 A1
(43) Pub. Date: Jun. 27, 2002

(54) Semiconductor integrated circuit device and manufacturing method thereof

(76) Inventors: Shigeaki Okawa, Tochigi (JP); Toshiyuki Ohkoda, Gunma (JP)

Correspondence Address: CHRIS T. MIZUMOTO, Fish & Richardson P.C., Suite 2800, 45 Rockefeller Plaza, New York, NY, 10111, US

(21) Appl. No.: 10/032,236

(22) Filed: Dec. 21, 2001

(30) Foreign Application Priority Data
Dec. 25, 2000 (JP) P. 2000-392223

(51) Int. Cl. H01L 29/70; H01L 27/102; H01L 27/082; H01L 31/11

(52) U.S. Cl. 257/565

(57) ABSTRACT

In the semiconductor integrated circuit device, two epitaxial layers and are formed on a substrate, and they are electrically isolated by a P⁺ type isolating region into three island regions. A diode element is formed in the first island region, and an N⁺ type well region is formed in an overlapping relationship with an N⁺ type cathode lead region. Since this reduces the resistance of an N-type region at a PN junction to reduce a forward voltage VBEF, a forward current (If) capacity can be significantly improved.

### BACKGROUND OF THE INVENTION

The present invention relates to a semiconductor integrated circuit device incorporating a spark killer diode which is suitable for protecting an output transistor.

For example, as shown in FIG. 11, a three-phase motor driver employs a circuit configuration in which pairs of series-connected transistors (Tr1 and Tr2, Tr3 and Tr4, Tr5 and Tr6) are connected in parallel between a DC power source VCC and the ground GND and in which output terminals provided between the pairs of transistors Tr1 and Tr2, Tr3 and Tr4, and Tr5 and Tr6 are connected to a motor M.

In the case of an inductive load as described above, electromotive forces are generated in forward and reverse directions when the motor is rotated and stopped. In the conventional art, protective diodes are connected between the collectors and emitters of the integrated series-connected transistors, and the diodes 4 are turned on when the potential at the output terminals becomes lower than the ground potential or higher than the potential VCC because of the electromotive force in the reverse direction to lead the electromotive force to a fixed potential, thereby protecting the interior of the integrated circuit including the series-connected transistors. Especially, when a current as great as several amperes is applied to the diodes 4, the diodes 4 are configured as separate components.

There are demands from users for integration of the diodes 4 in order to reduce the number of components of an apparatus. However, when diodes to which a current as great as several amperes is applied are integrated, a parasitic current is caused by a parasitic transistor effect which inevitably occurs in the integrated circuit, and this can cause a wattless current and can lead to latch-up in the worst case.

For example, the structure disclosed in Japanese patent publication No. H06-104459 was proposed as a structure for preventing a parasitic current.

Referring to FIG. 12, an N⁺ type buried layer 3 is provided between a P type semiconductor substrate 1 and an N type semiconductor substrate 2, and a P⁺ type isolating region 4 is diffused from a surface of the semiconductor layer 2 to the semiconductor substrate 1 such that it encloses the buried layer 3 to form an island 5. A P⁺ type buried layer 6 is formed on the buried layer 3 such that they partially overlap each other. An N⁺ type lead region 7 is provided such that it encloses the P⁺ type buried layer 6 and extends from a surface of the semiconductor layer 2 to the N⁺ type buried layer 3, and an N⁺ type diffused region 8 is formed in the enclosed region. Further, a P⁺ type lead region 9 is provided in the region enclosed by the lead region 7 such that it encloses the diffused region 8 and extends from the semiconductor layer 2 to the P⁺ type buried layer 6. Furthermore, a cathode 10 and an anode 11 are provided in the diffused region 8 and the P⁺ type lead region 9 respectively, and the anode 11 is electrically connected to the N⁺ type lead region 7.

That is, a diode is formed by the P⁺ type lead region 9 and the P⁺ type buried layer 6 serving as an anode region and the N type semiconductor region enclosed by the N⁺ type diffused region 8 and lead region 9 serving as a cathode region.

In such a diode element, a PNP type parasitic transistor Tr2 is formed by the N⁺ type buried layer 3 serving as the base, the P⁻ type buried layer 6 serving as the emitter, and the P type semiconductor substrate 1 and P⁺ type isolating region 4 serving as the collector. Since the base and emitter of the parasitic transistor Tr2 is at the same potential through the connection of the anode, it is possible to prevent the parasitic PNP transistor from being turned on.

In the conventional semiconductor integrated circuit device described above, since electromotive forces in forward and reverse directions are generated when the motor is rotated and stopped in the case of an inductive load as shown in FIG. 11, protective diodes are connected between the collectors and emitters of the integrated series-connected transistors, and the diodes 4 are turned on when the potential at the output terminals becomes lower than the ground potential or higher than the potential VCC because of the electromotive force in the reverse direction to lead the electromotive force to a fixed potential, thereby protecting the interior of the integrated circuit including the series-connected transistors. Especially, when a current as great as several amperes is applied to the diodes 4, the diodes 4 are configured as separate components.

In order to satisfy demands for integration of the diodes 4 to achieve a reduction of the number of components of an apparatus, the diodes to which a current as great as several amperes is applied are integrated. In consideration to problems including a wattles current attributable to a parasitic current caused by a parasitic transistor effect which inevitably occurs in the integrated circuit, a structure as shown in FIG. 12 is employed in which diodes are incorporated in an IC.

In the structure shown in FIG. 12, although the diode can be incorporated in the IC, a problem has arisen in that it is impossible to prevent a leakage current to the substrate 1 completely.

### SUMMARY OF THE INVENTION

The present invention has been made taking the above-described problem in the conventional art into consideration, and a semiconductor integrated circuit device according to the invention comprises: a semiconductor substrate of a first conductivity type; a first epitaxial layer of an opposite conductivity type formed on a surface of the substrate; a second epitaxial layer of the opposite conductivity type formed on a surface of the first epitaxial layer; an isolating region of the first conductivity type for isolating the first and second epitaxial layers to form first, second and third island regions; a buried layer of the opposite conductivity type formed between the substrate and the first epitaxial layer; a diode element formed in the first island region, a vertical transistor of a first conductivity type formed in the second island region, and a vertical transistor of the opposite conductivity type formed in the third island region; an anode lead region of the opposite conductivity type, an anode lead region of the first conductivity type, and a cathode lead region of the opposite conductivity type of the diode element formed in the first island region; a collector lead region, an emitter region, and a base lead region of the vertical transistor of the first conductivity type formed in a well region of the opposite conductivity type formed in the second island region; a collector lead region, an emitter region, and a base lead region of the transistor of the opposite conductivity type formed in the third island region; and a well region of the opposite conductivity type formed to overlap with the cathode lead region of the opposite conductivity type in the first island region.

Preferably, in the semiconductor integrated circuit device according to the invention, the well region of the opposite conductivity type is formed in an overlapping relationship with the cathode lead region of the opposite conductivity type of the diode element. Since this reduces the resistance of an N-type region at a PN junction to reduce a forward voltage VBEF, it is possible to provide a semiconductor integrated circuit device in which a forward current (If) capacity is significantly improved.

In order to solve the above-describe problem, according to the present invention, a method of manufacturing a semiconductor integrated circuit device in which a diode element, a vertical transistor of a first conductivity type, and a vertical transistor of the opposite conductivity type are formed on a common substrate, comprises the steps of: providing a semiconductor substrate of the first conductivity type; diffusing an impurity in the substrate to form a buried layer in each of regions where the diode element, the vertical transistor of the first conductivity type, and the vertical transistor of the opposite conductivity type are to be formed; forming a first epitaxial layer of the opposite conductivity type on the substrate; diffusing an impurity on the first epitaxial layer to form a buried layer in each of regions where the diode element, the vertical transistor of the first conductivity type, and the vertical transistor of the opposite conductivity type are to be formed; forming a second epitaxial layer on the first epitaxial layer; and diffusing an impurity on the second epitaxial layer to form well regions of the opposite conductivity type in the regions where the diode element and the vertical transistor of the first conductivity type are to be formed at the same step. According to the method of manufacturing a semiconductor integrated circuit device of the invention, preferably, well regions of the opposite conductivity type are formed in the regions to form the diode element and the vertical transistor of the first conductivity type simultaneously, which allows the structure of the semiconductor integrated circuit device according to the invention to be formed easily.

### BRIEF DESCRIPTION OF THE DRAWINGS

FIG. 1 is a sectional view illustrating a semiconductor integrated circuit device according to the invention;

FIG. 2 A is an enlarged sectional view illustrating diode elements in the semiconductor integrated circuit device in FIG. 1 according to the invention, and FIG. 2B is an equivalent circuit diagram of the same;

FIG. 3 is a sectional view illustrating a method of manufacturing a semiconductor integrated circuit device according to the invention;

FIG. 4 is a sectional view illustrating the method of manufacturing a semiconductor integrated circuit device according to the invention;

FIG. 5 is a sectional view illustrating the method of manufacturing a semiconductor integrated circuit device according to the invention;

FIG. 6 is a sectional view illustrating the method of manufacturing a semiconductor integrated circuit device according to the invention;

FIG. 7 is a sectional view illustrating the method of manufacturing a semiconductor integrated circuit device according to the invention;

FIG. 8 is a sectional view illustrating the method of manufacturing a semiconductor integrated circuit device according to the invention;

FIG. 9 is a sectional view illustrating the method of manufacturing a semiconductor integrated circuit device according to the invention;

FIG. 10 is a sectional view illustrating the method of manufacturing a semiconductor integrated circuit device according to the invention;

FIG. 11 is a circuit diagram illustrating a conventional semiconductor integrated circuit device; and

FIG. 12 is a sectional view illustrating diode elements in the conventional semiconductor integrated circuit device.

### DETAILED DESCRIPTION OF THE PREFERRED EMBODIMENT

An embodiment of the invention will now be described in detail with reference to the drawings.

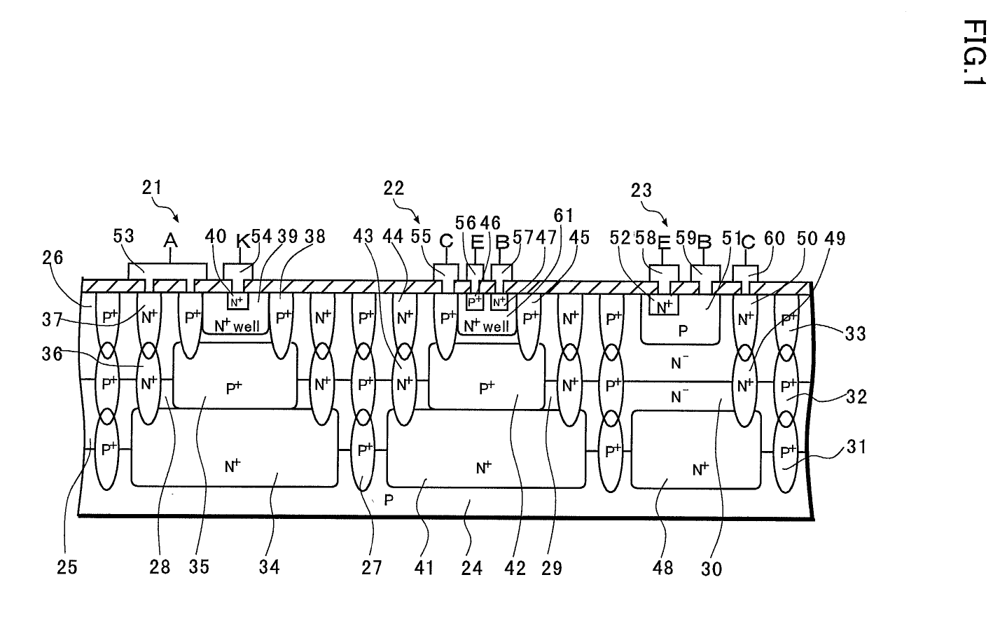

FIG. 1 is a sectional view of a semiconductor integrated circuit device incorporating a diode element 21, a vertical PNP transistor 22, and an NPN transistor 23.

On a P type single crystal silicon substrate 24, a first epitaxial layer 25 having a thickness of 2 to 10 μm and a second epitaxial layer 26 having a thickness of 6 to 10 μm are formed such that the total thickness of the two layers becomes 8 to 16 μm. The substrate 24 and the first and second epitaxial layers 25 and 26 are electrically isolated by a P⁺ type isolating region 27 which penetrates them to form a first island region 28 for forming the diode element 21, a second island region 29 for forming the vertical PNP transistor 22, and a third island region 30 for forming the NPN transistor 23.

The isolating region 27 includes a first isolating region 31 which is diffused in the vertical direction from a surface of the substrate 24, a second isolating region 32 which is diffused in the vertical direction from the boundary between the first and second epitaxial layers 25 and 26, and a third isolating region 33 which is formed from a surface of the second epitaxial layer 26, the three regions being connected with each other to isolate the first and second epitaxial layers 25 and 26 in the form of islands.

The diode element 21 formed in the first island region 23 basically has a structure similar to that of the vertical PNP transistor 22. Specifically, a P⁺ type buried layer 35 is formed at the boundary between the first and second epitaxial layers 25 and 26 as an anode region, and a P⁺ type diffused region 38 which extends from a surface of the second epitaxial layer 26 to the P⁺ type buried layer 35 is formed as an anode lead region. The N⁻ type second epitaxial layer 26 enclosed by the P⁺ type regions is formed as a cathode region to configure a PN junction diode. At this time, an N⁺ type diffused region 37 may be formed in the second epitaxial layer 26 as an anode region, and the P⁺ type diffused region 38 and the N⁺ type diffused region 37 may be shorted to form an anode lead region. The resultant element may be regarded as a diode formed by shorting the base and collector of an NPN transistor.

In the semiconductor integrated circuit device according to the invention, an N⁺ type well region 39 is formed in the N⁻ type second epitaxial layer 26 enclosed by the P⁺ type region formed as a cathode region. Since the N⁺ type well region 39 reduces the resistance of the N type region at the PN junction to reduce a forward voltage VBEF, a forward current (If) capacity can be significantly improved.

The surface of the second epitaxial layer 26 is coated with a silicon oxide film, and various aluminum electrodes are provided through contact holes formed in the oxide film. A ground potential GND is applied to the substrate 24 for isolation of the junction.

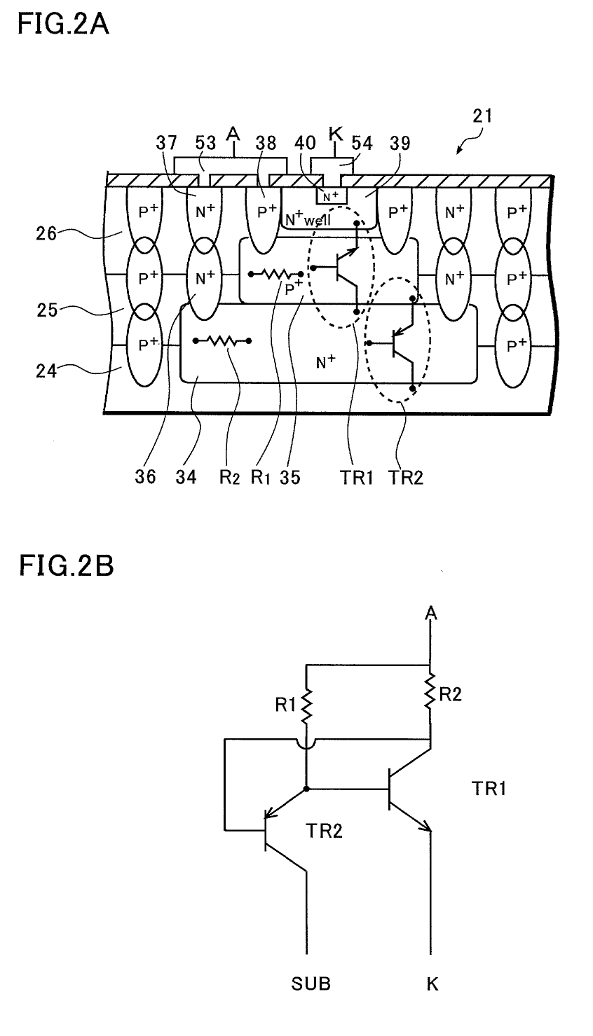

FIG. 2A is an enlarged cross section of the diode element 21, and FIG. 2B is an equivalent circuit diagram showing parasitic transistors. A description will now be made on operations of parasitic transistors that dominate a leakage current to the substrate 24.

Referring to FIG. 2A, a parasitic NPN transistor TR1 is formed by the N⁺ type first buried layer 34 serving as the collector, P⁺ type first buried layer 35 serving as the base, and N⁺ well region 39 serving as the emitter. On the other hand, a parasitic PNP transistor TR2 is formed by the P type substrate 24 serving as the collector, the N⁺ type first buried layer 34 serving as the base, and P⁺ type first buried layer 35 serving as the emitter.

Referring to FIG. 2B, the base and collector of the parasitic NPN transistor TR1 are shorted by an anode 53, and the base and emitter of the parasitic PNP transistor TR2 are similarly shorted. At this time, a resistive component R1 originating from the P⁺ type diffused region 38 and P⁺ type buried layer 35 is connected between the base and collector of the parasitic NPN transistor TR1, and a resistive component R2 originating from the N⁺ type diffused region 37, the N⁺ type second buried layer 36, and the N⁺ type first buried layer 34 is connected between the base and emitter of the parasitic PNP transistor TR2. In the structure of the diode element 21 according to the invention, the value of the resistive component R1 of the parasitic NPN transistor TR1 is quite small because of the configuration in which the P⁺ type diffused region 38 and P⁺ type buried layer 35 are connected with each other. The value of the resistive component R2 of the parasitic PNP transistor TR2 is also quite small because the N⁺ type diffused region 37, N⁺ type second buried layer 36, and N⁺ type first buried layer 34 are connected with each other.

According to the invention, since the resistance of the cathode region can be reduced as a result of the formation of the N⁺ type well region 39, a forward current (If) capacity can be improved.

Since the value of the resistive component R2 connected between the base and emitter of the parasitic PNP transistor TR2 can be small, the base potential of the parasitic PNP transistor TR2 (the potential of the N⁺ type first buried layer 34) can be maintained at a value higher than the emitter potential (the potential of the P⁺ type buried layers 35). This makes it possible to prevent the parasitic PNP transistor TR2 from being turned on, thereby keeping a leakage current to the substrate 24 at a small value.

As a result, for example, while a leakage current of 100 mA flows to the substrate 24 when a current of 1 A flows through the conventional structure, the leakage current can be reduced to 20 mA in the inventive structure (when the resistance of the resistive component R2 is 8 Ω).

In the vertical PNP transistor 22 formed in the second island region 29, a P⁺ type buried layer 42 is formed as a collector region at the boundary between the first and second epitaxial layers 25 and 26, and a P⁺ type diffused region 45 extending from a surface of the second epitaxial layer 26 to the P⁺ type buried layer 42 is formed as a collector lead region. The vertical PNP transistor 22 is formed by forming an N⁺ type well region 61 as a base region in the N⁻ type second epitaxial layer 26 enclosed by those P⁺ type regions and by forming a P⁺ type diffused region 46 and an N⁺ type diffused region 47 as an emitter region and a base lead region respectively in the N⁺ type well region 61. Further, an N⁺ type diffused region 44 is formed such that it encloses the P⁺ type diffused region 45 and is connected with the first buried layer 27 through an N⁺ type second buried layer 43 to apply a power supply voltage Vcc from an electrode which is not shown or the potential of an emitter electrode 56. The purpose is to prevent the generation of a parasitic PNP transistor formed by the P⁺ type diffused region 45 serving as the emitter, the second island region 29 serving as the base, and the P⁺ type isolating region 27 as the collector. Thus, the vertical PNP transistor can be a PNP transistor that is preferably used for great currents.

The NPN transistor 23 formed in the third island region 30 is configured by forming the third island region 30 as a collector region, the P type diffused region as a base region, and the N⁺ type diffused region as an emitter region. A first N⁺ type buried layer 48 is formed between the substrate 24 and the first epitaxial layer 25, and a second N⁺ type buried layer 49 is formed at the boundary between the first and second epitaxial layers 25 and 26, those layers being connected with each other. Further, an N⁺ type diffused region 50 is provided as a collector lead region, and the N⁺ type diffused region 50 is also formed in connection with the second N⁺ type buried layer 49. By forming regions with a high concentration and low resistance under a collector electrode 60 as described above, the saturation resistance Vce (sat) of the NPN transistor 23 is reduced. Thus, the NPN transistor 23 has a high withstand voltage and accommodates a great current, and it is therefore suitable for use in circuits such as motor drivers.

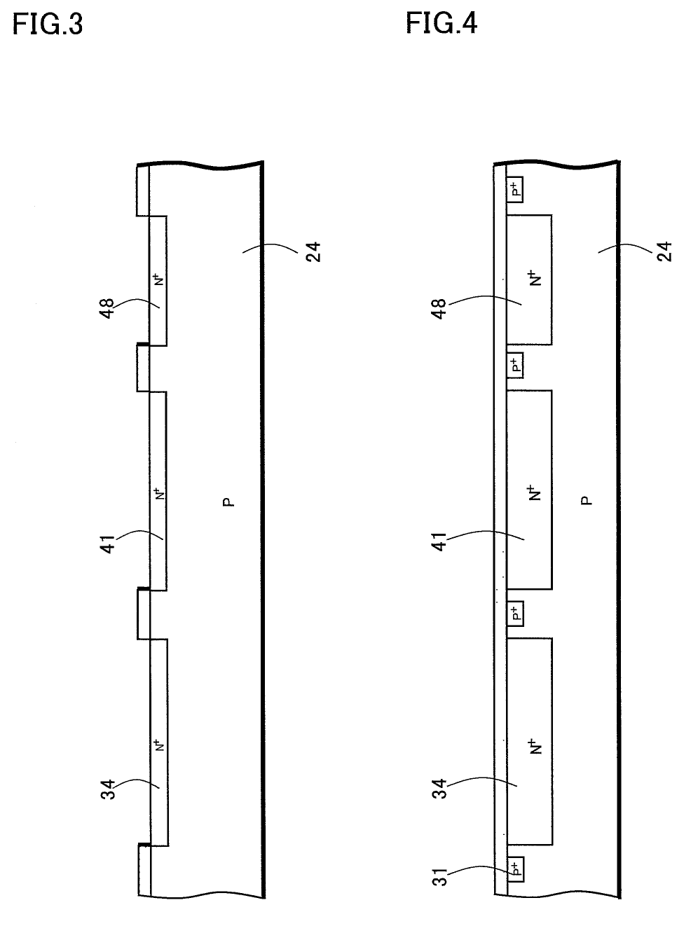

A method of manufacturing a semiconductor integrated circuit device according to the invention as shown in FIG. 1 will now be described with reference to FIGS. 3 through 10.

First, as shown in FIG. 3, the P⁻ type single crystal silicon substrate 24 is provided; the surface of the substrate 24 is thermally oxidized to form an oxide film, and photo-etching is performed in regions of the oxide film corresponding to the N⁺ type buried layers 34, 41, and 48 to provide a selective mask. Then, phosphorous (P) is diffused on the surface of the substrate 24 to form the N⁺ type buried layers 34, 41, and 48.

Except for phosphorous (P), antimony (Sb) or arsenic (As) may be used as an impurity to form the N⁺ type buried layers 34, 41, and 48

Next, as shown in FIG. 4, ion implantation is carried out to form the first isolating region 31 of the P⁺ type isolating region 27. After removing the oxide film used as a selective mask in FIG. 3 completely, a well-known photolithographic technique is used to form a photo-resist (not shown) as a selective mask having an opening in a part thereof where the P⁺ type first isolating region 31 is to be formed. Then, ions of a P type impurity, e.g., boron (B) are implanted with an acceleration voltage of 160 keV and in a dose of 1.0×10¹⁴/cm². The photo-resist is thereafter removed.

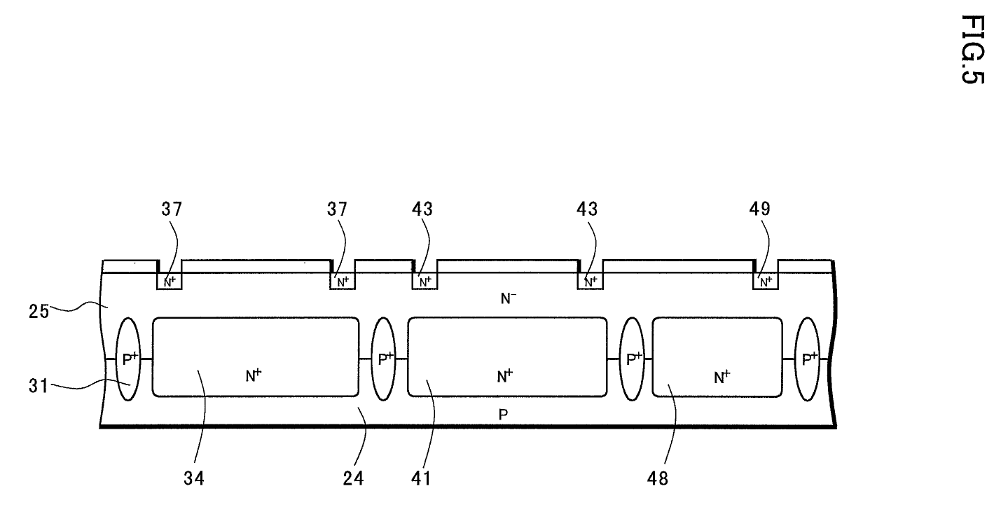

Next, as shown in FIG. 5, the substrate 24 is placed on a susceptor of an epitaxial growth apparatus after removing the oxide film completely; the substrate 24 is heated by a lamp at a high temperature of about 1140° C.; and SiH₂Cl₂ gas and H₂ gas are introduced into the reaction tube. As a result, the first epitaxial layer 25 is grown with a thickness of 2.0 to 10.0 μm on a low concentration epitaxial basis (ρ=1.25 Ω·cm). The surface of the first epitaxial layer 25 is then thermally oxidized to form an oxide film, and photo-etching is thereafter performed in regions of the oxide film corresponding to the N⁺ type second buried layers 37, 43, and 49 to provide a selective mask. Then, phosphorous (P) is diffused on the surface of the substrate 24 to form the N⁺ type buried layers 34, 41 and 48.

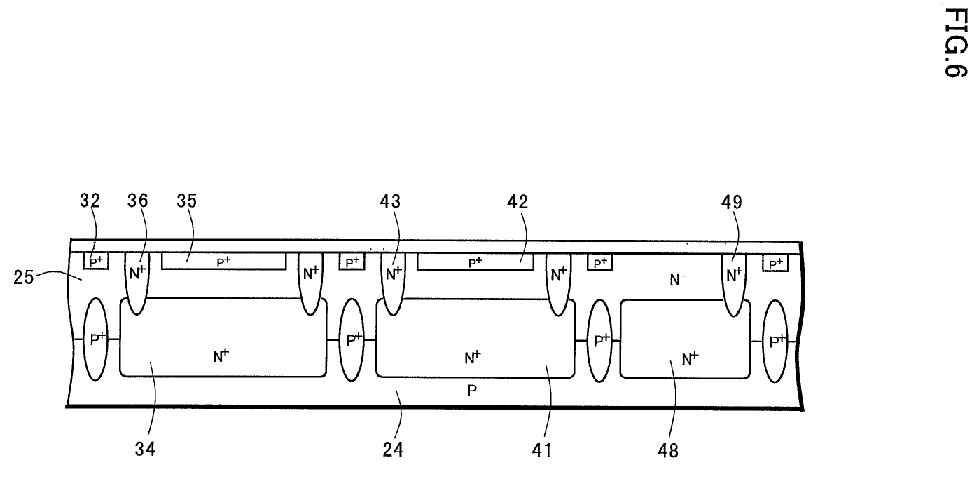

Next, as shown in FIG. 6, the surface of the first epitaxial layer 25 is thermally oxidized again after removing the oxide film completely, and a well-known photolithographic technique is used to form a photo-resist (not shown) as a selective mask having openings in parts thereof where the P⁺ type buried layers 35 and 42 and the P⁺ type second isolating region 39 are to be formed. Then, ions of a P type impurity, e.g., boron (B) are implanted with an acceleration voltage of 40 keV and in a dose of 3.0×10¹³/cm². The photo-resist is there after removed. At this time, the second N⁺ type buried layers 36, 43, and 49 are simultaneously diffused and are connected with the first N⁺ type buried layers 34, 41, and 48.

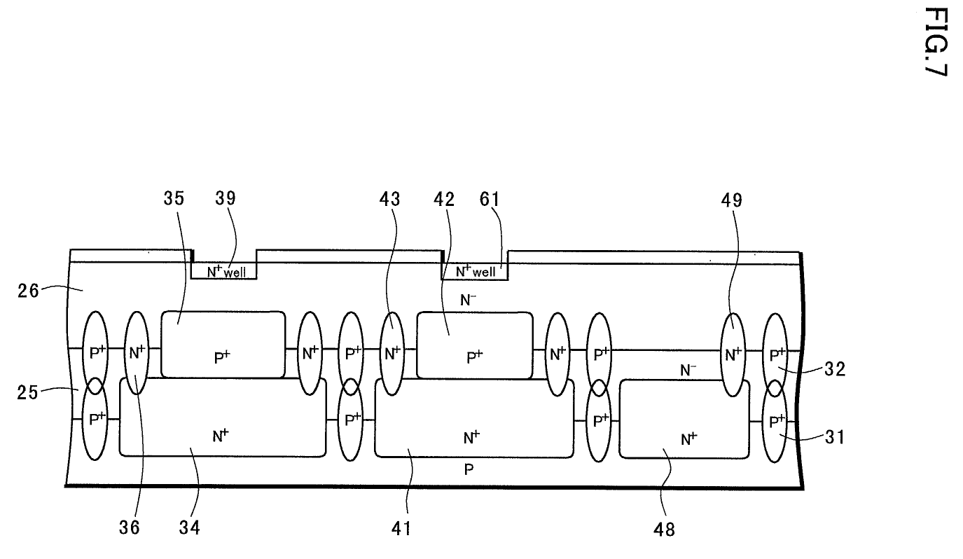

Next, as shown in FIG. 7, the substrate 24 is placed on the susceptor of the epitaxial growth apparatus after removing the oxide film completely; the substrate 24 is heated by the lamp at a high temperature of about 1140° C.; and SiH₂Cl₂ gas and H₂ gas are introduced into the reaction tube. As a result, the second epitaxial layer 26 is grown on the first epitaxial layer 25 with a thickness of 6.0 to 10.0 μm on a low concentration epitaxial basis (ρ=1.25 Ω·cm). The surface of the second epitaxial layer 26 is then thermally oxidized to form an oxide film, and a well-known photolithographic technique is thereafter used to form a photo-resist (not shown) as a selective mask having openings in parts thereof where the N⁺ type well regions 39 and 61 are to be formed. Then, ions of an N type impurity, e.g., phosphorous (P) are implanted with an acceleration voltage of 160 keV and in a dose of 1.0×10¹²/cm². The photo-resist is thereafter removed. At this time, the P⁺ type buried layers 35 and 42 and the P⁺ type second isolating region 32 are simultaneously diffused and are connected with the first N⁺ type buried layers 34 and 41 and P⁺ type first isolating region 31.

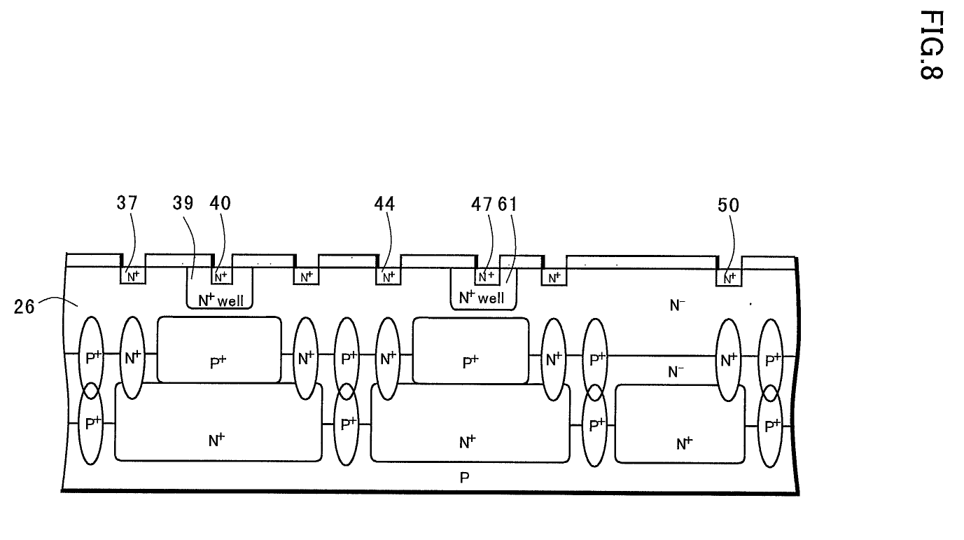

Next, as shown in FIG. 8, the surface of the second epitaxial layer 26 is thermally oxidized to form an oxide film, and photo-etching is performed in regions of the oxide film corresponding to the N⁺ type collector lead regions 37, 44, and 50 and the base lead region 47 to provide a selective mask. Then, phosphorous (P) is diffused on the surface of the second epitaxial layer 26 to form the N⁺ type diffused regions 37, 44, and 50 and the base lead region 47.

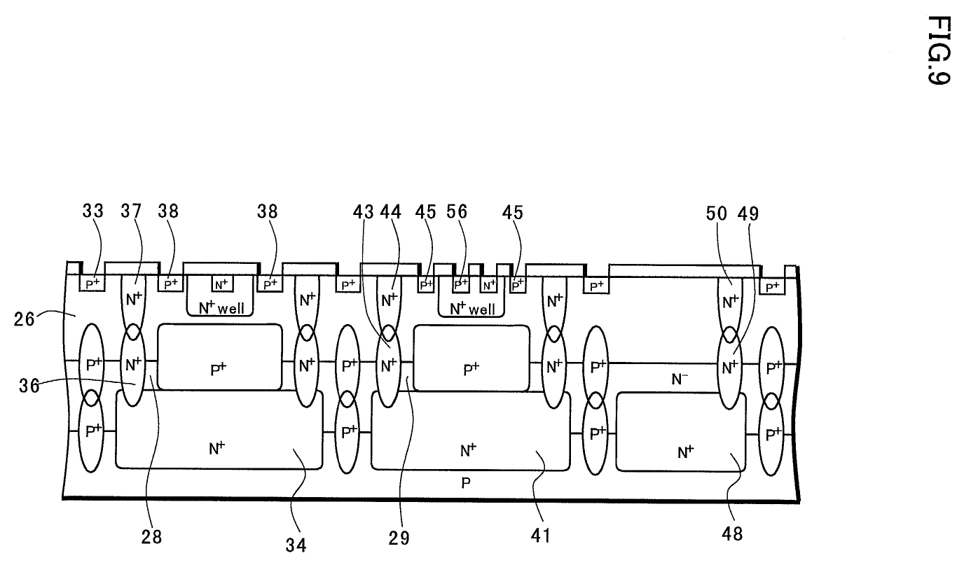

Next, as shown in FIG. 9, the surface of the second epitaxial layer 26 is thermally oxidized again after removing the oxide film completely, and a well-known photolithographic technique is used to form a photo-resist (not shown) as a selective mask having openings in parts thereof where the P⁺ type diffused regions 38 and 45, the P⁺ type emitter region 46, and the P⁺ type third isolating region 33 are to be formed. Then, ions of a P type impurity, e.g., boron (B) are implanted with an acceleration voltage of 40 keV and in a dose of 3.0×10¹³/cm². The photo-resist is thereafter removed. At this time, the second N⁺ type buried layers 36, 43, and 49 are simultaneously diffused and are connected with the first N⁺ type buried layers 34, 41, and 48. The N⁺ type diffused regions 37, 44, and 50 are also diffused simultaneously and are connected with the second N⁺ type buried layers 36, 43, and 49, respectively. As a result, the diode element 21 is completed in the first island region 28, and the vertical PNP transistor 22 is completed in the second island region 29.

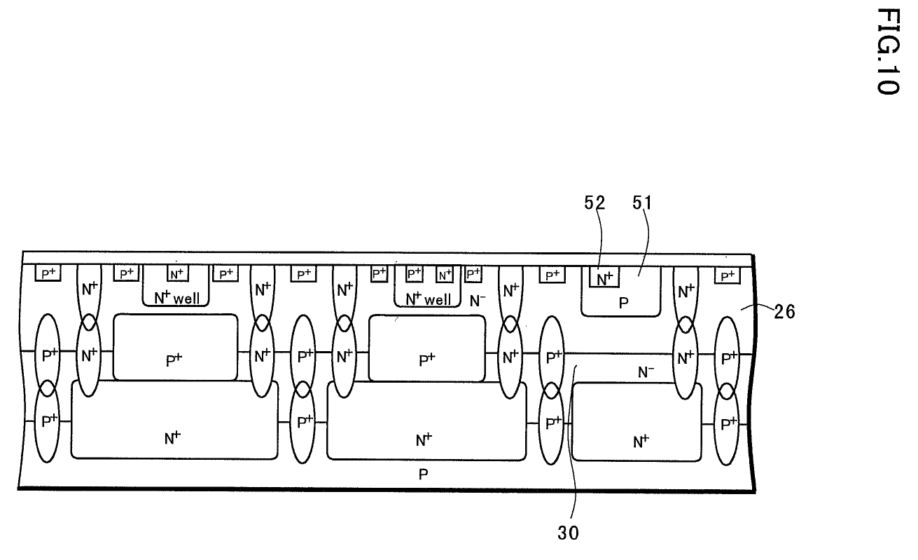

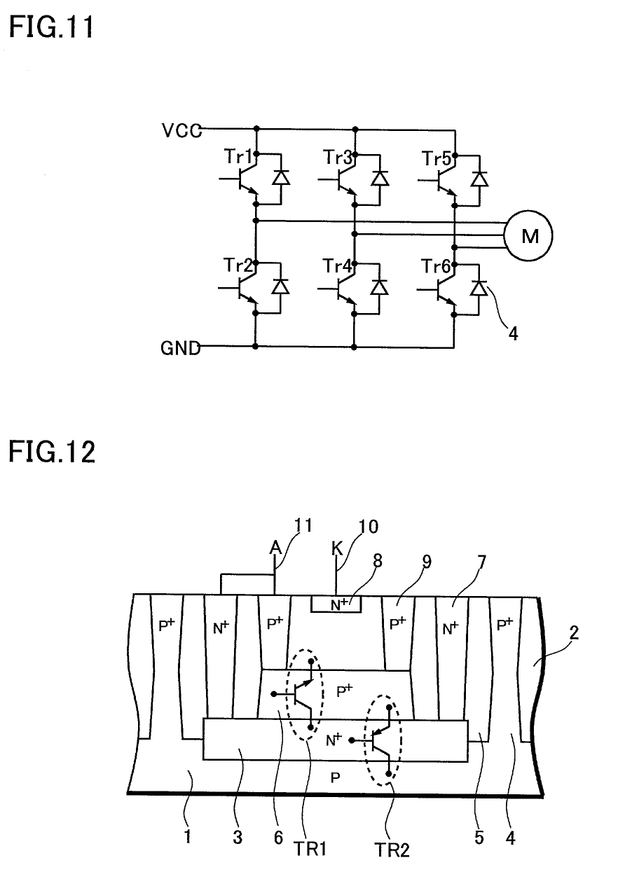

Next, as shown in FIG. 10, the NPN transistor 23 is completed by forming the P type base region 51 and the N⁺ type emitter region 52 in the third island region 30. Thereafter, as shown in FIG. 1, an anode 53 and a cathode 54 are formed at the diode element 21; a collector electrode 55, an emitter electrode 56, and a base electrode 57 are formed at the vertical PNP transistor 22; and an emitter electrode 58, abase electrode 59, and a collector electrode 60 are formed at the NPN transistor 23 from aluminum, which connects those elements to external electrodes.

According to the invention, in the diode element of the semiconductor integrated circuit device, the N⁺ type well region is formed in the N⁻ type second epitaxial layer enclosed by the P⁺ type region formed as a cathode region. Since the N⁺ type well region reduces the resistance of the N type region of the PN junction to reduce a forward voltage VBEF, a forward current (If) capacity can be significantly improved.

Further, by forming the N⁺ type well region according to the invention, the current amplification factor of the parasitic transistor TR1 formed in the diode element is improved; the current amplification factor of the parasitic transistor TR2 can be reduced; and the effect of suppressing a leakage current to the substrate is improved. This makes it possible to integrate spark killer diodes suitable for protection of output transistors with a semiconductor integrated circuit device, and this contributes to reduction of the size of electronic apparatuses and improvement of the density of the same.

What is claimed is:

1. A semiconductor integrated circuit device comprising:
a semiconductor substrate of a first conductivity type;
a first epitaxial layer of an opposite conductivity type formed on a surface of the substrate;
a second epitaxial layer of the opposite conductivity type formed on a surface of the first epitaxial layer;
an isolating region of the first conductivity type for isolating the first and second epitaxial layers to form first, second and third island regions;
a buried layer of the opposite conductivity type formed between the substrate and the first epitaxial layer;
a diode element formed in the first island region, a vertical transistor of a first conductivity type formed in the second island region, and a vertical transistor of the opposite conductivity type formed in the third island region;
an anode lead region of the opposite conductivity type, an anode lead region of the first conductivity type, and a cathode lead region of the opposite conductivity type of the diode element formed in the first island region;
a collector lead region, an emitter region, and a base lead region of the vertical transistor of the first conductivity type formed in a well region of the opposite conductivity type formed in the second island region;
a collector lead region, an emitter region, and a base lead region of the transistor of the opposite conductivity type formed in the third island region; and
a well region of the opposite conductivity type formed to overlap with the cathode lead region of the opposite conductivity type in the first island region.

2. The semiconductor integrated circuit device according to claim 1, wherein the well region of the opposite conductivity type formed in the first island region and the well region of the opposite conductivity type formed in the second island region are diffused layers formed at the same diffusing step.

3. A method of manufacturing a semiconductor integrated circuit device in which a diode element, a vertical transistor of a first conductivity type, and a vertical transistor of the opposite conductivity type are formed on a common substrate, comprising:
providing a semiconductor substrate of the first conductivity type;
diffusing an impurity in the substrate to form a buried layer in each of regions where the diode element, the vertical transistor of the first conductivity type, and the vertical transistor of the opposite conductivity type are to be formed;
forming a first epitaxial layer of the opposite conductivity type on the substrate;
diffusing an impurity on the first epitaxial layer to form a buried layer in each of regions where the diode element, the vertical transistor of the first conductivity type, and the vertical transistor of the opposite conductivity type are to be formed;
forming a second epitaxial layer on the first epitaxial layer; and
diffusing an impurity on the second epitaxial layer to form well regions of the opposite conductivity type in the regions where the diode element and the vertical transistor of the first conductivity type are to be formed at the same step.

4. The method of manufacturing a semiconductor integrated circuit device according to claim 3, wherein the well region of the opposite conductivity type formed in the region to form the diode element is formed as a cathode region and in that the well region of the opposite conductivity type formed in the region to form the vertical transistor of the first conductivity type is formed as a base region.
